(19) United States
(12) Patent Application Publication
(10) Pub. No.: US 2007/0258195 A1
(43) Pub. Date: Nov. 8, 2007

(54) Fastening assembly for memory riser card

(75) Inventors: Yao-Ming Liu, Taipei (TW); Chun-Hung Lee, Taipei (TW); Shih-Tsung Chen, Taipei (TW)

Correspondence Address: BIRCH STEWART KOLASCH & BIRCH, PO BOX 747, FALLS CHURCH, VA, 22040-0747, US

(73) Assignee: TYAN COMPUTER CORPORATION

(21) Appl. No.: 11/482,788

(22) Filed: Jul. 10, 2006

(30) Foreign Application Priority Data
May 4, 2006 (TW) 095115817

(51) Int. Cl. H05K 5/00; H05K 7/00

(52) U.S. Cl. 361/679

(57) ABSTRACT

A fastening assembly for riser cards equipped with memory modules includes holders and latches. Each of the holders has bars and pillars to form a solid framework and couple to a mother board. The edges of the riser cards are held by holding grooves on the pillars to enable the riser cards sliding therein and insert towards riser sockets on the mother board. Meanwhile, the latches slip to latch the holding grooves to limit the movement of the riser cards. Thus, the fastening assembly improves the fixing strength of the riser cards and prevents from moving off while impacted, vibrated or crashed.

### BACKGROUND OF THE INVENTION

1. Field of Invention

The present invention relates to an assembly for fastening components onto a computer system, and more particularly to a fastening assembly dedicated to a riser card of memory module.

2. Related Art

In a computer system, the most important part is the mother board that carries various electrical component; while a CPU (Central Processing Unit), processing tasks of data operation as the most important component on the mother board, may be so-called the heart of the whole computer system. However, without the supports of other peripheral elements, the CPU can not function normally. Even it is the major operation component.

Basically, a computer system is primarily constituted of four parts, CPU, memory, hard disc, and graphic card. A CPU dominates the calculation, and the programs waited to be executed are “temporarily” stored in a memory which is considered the first storage unit when its playing role is the compared with a hard disc's. Only when the data waited to be processed by CPU has not been loaded in a memory, the system will enter and search in a hard disc. Therefore, the hard disc plays the role of “auxiliary memory.” However, after the computer is shutdown, the content stored in system memory will disappear along with electricity cutoff. In other words, the content in a memory is under a temporary-stored status, unlike a hard disc, the data inside is stored permanently.

While a memory has a higher and higher capacity, besides the original role of systematizing and storing software, it has been started to be utilized by other hardware components in order to achieve the purpose of lowering cost and raising efficiency, i.e. the interface structure of AGP or PCI Express is designed to store image material by using the system memory through Graphic Processing Unit (GPU) so as to accelerate the processing speed and performance of video data.

Generally speaking, the number of memory slots is limited in a computer system. For a common personal computer, 3 memory slots are the maximum and the extendable capacity is thus limited. The extendable performance is clearly not enough for some systems like working stations or super computers. Later, the so-called riser card is developed. Please refer to FIG. 1. The riser card 11 is inserted into the riser socket (not shown) of common PCI interface and has multiple memory sockets 12. Usually the riser card 11 has 8 memory sockets 12 for memory modules. However, unlike a common PCI interface, when all the memory sockets 12 are inserted with memory modules, the riser card 11 will be bended due to the increased weights of the memory modules and the shape thereof will be deformed, and the supporting strength provided from the insertion of the riser card 11 into the PCI interface slot is not enough. A design of additional fixing module is then needed. However, the space between the slots of PCI interface is too small to allow a changeable design. Therefore, how to improve the fixing module for the riser card has become a significant issue for those skilled in the art.

### SUMMARY OF THE INVENTION

To solve the technical problems existed in the prior art, the present invention discloses a fastening assembly for fixing multiple riser cards equipped with memory modules. Thus, the fastening assembly improves the fixing strength of the riser cards and prevents from moving off while impacted, vibrated or crashed.

In an embodiment of the present invention, a fastening assembly is provided for fixing plural riser cards. Each of the riser cards has plural memory sockets for configuring with plural memory modules. The riser cards are inserted into plural corresponsive riser sockets of a mother board respectively. The fastening assembly includes at least one holder and at least one latch. The holder is configured adjacent to the riser cards, having a top bar, at least one pillar and one or more holding grooves. The pillar is extended from the top bar and coupled to the mother board, while the holding grooves is located on the pillar, holding the edges of the corresponsive riser cards, and enabling the riser cards to slid therein and insert towards the riser sockets. The latch is configured on the top bar of the holder for moving relatively to the top bar and blocking the holding grooves, thereby preventing the riser cards from moving off.

In an embodiment of the present invention, the fastening assembly further includes at least one handle configured on the top of each of the riser cards. The fastening assembly may further include at least one fixing piece to fasten the pillar with the mother board, wherein the fixing piece is parallel or perpendicular to the top bar. Furthermore, the latch may comprise a limiting slot to cooperate with a limiting member of the top bar for limiting the movement of the latch, wherein the limiting member is a positioning protrusion extended from the top bar, or a limiting screw. Practically, the latch may include a fixing screw for fastening the latch on the top bar. For certain cases, the latch may include a hook for hooking a terminal of the top bar. At the bottom of the pillar, the holder may further include a bottom bar configured thereof. Moreover, the top bar may further include a T-shaped protrusion to allow one end of the latch to insert therein and help to fasten the latch. Also, the holder may further include at least one triangle support around the bottom of the pillar.

In another embodiment of the present invention, a fastening assembly is provided for fixing plural riser cards. Each of the riser cards has plural memory sockets for configuring with plural memory modules. The riser cards are inserted into plural corresponsive riser sockets of a mother board respectively. The fastening assembly includes at least one holder and at least one latch. The holder is configured adjacent to the riser cards, having a top bar, at least one pillar and one or more holding grooves. The pillar is extended from the top bar and coupled to the mother board, while the holding grooves is located on the pillar, holding the edges of the corresponsive riser cards, and enabling the riser cards to slid therein and insert towards the riser sockets. The latch is configured on the riser cards to couple with the top bar of the holder and prevent the riser cards from moving off.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is an explanatory drawing of a riser card in the prior art.

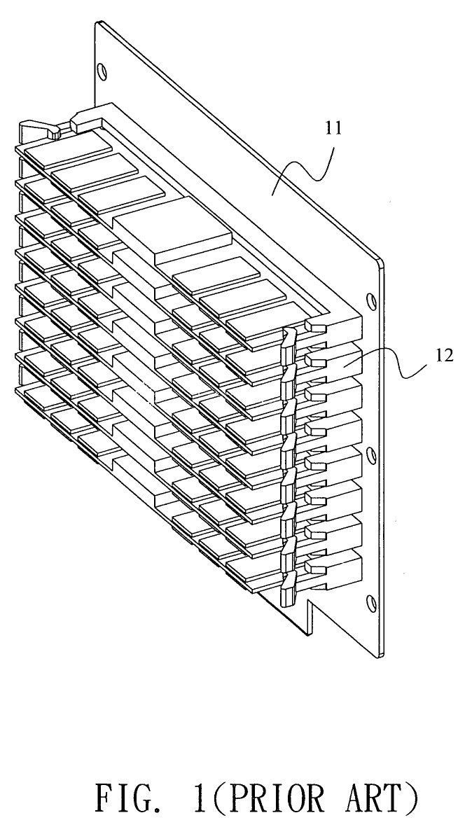

FIG. 2 is an explanatory drawing according to the present invention, showing the fastening assembly couples the riser cards onto the mother board.

FIG. 3 is a decomposition drawing according to the present invention, showing the riser cards couples onto the mother board by the fastening assembly.

FIG. 4 is an explanatory drawing according to the present invention, showing the fixing pieces of the fastening assembly.

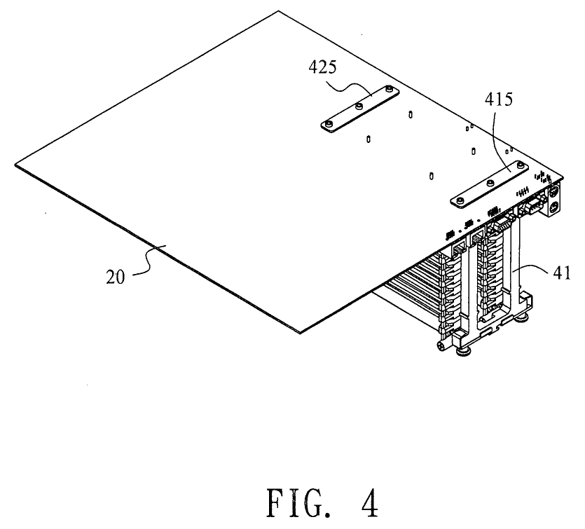

FIGS. 5A˜5D shows the configuration procedure of the fastening assembly for configuring the riser card according to the present invention.

FIG. 6 shows a protection slice of the riser card according to the present invention.

### DETAILED DESCRIPTION OF THE INVENTION

Content

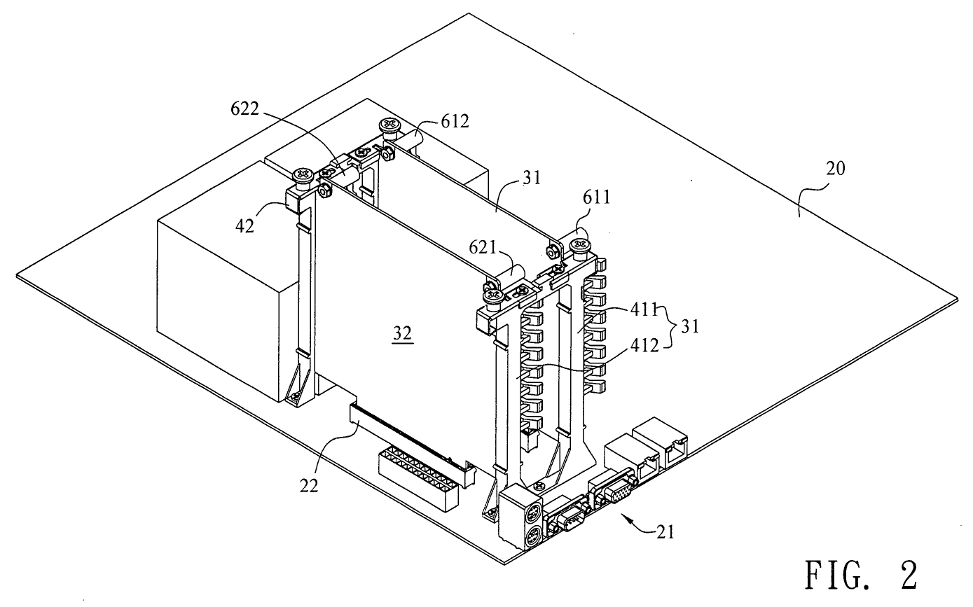

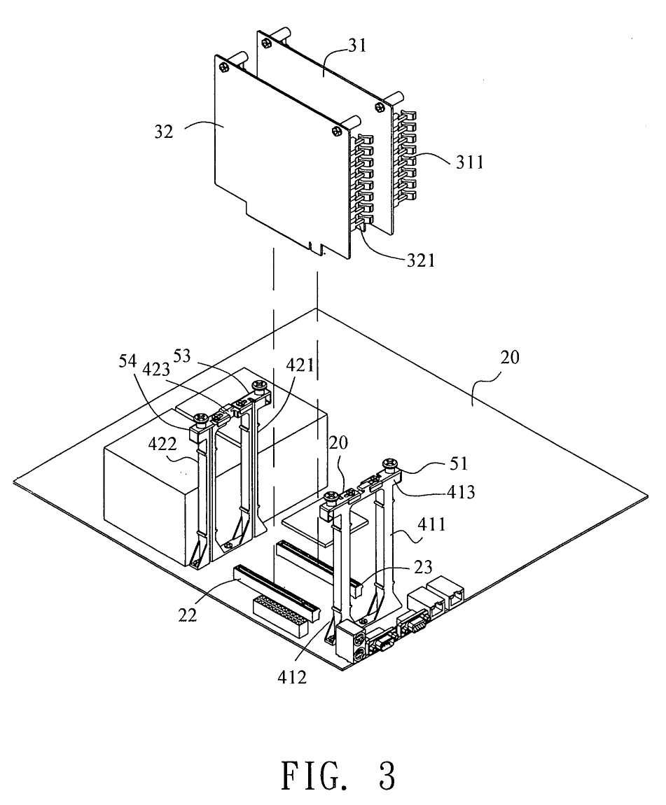

Please refer to FIGS. 2 and 3. An embodiment of a fastening assembly according to the present invention is applied to a mother board 20 that has plural communication ports 21 and plural riser sockets. Two riser sockets 22, 23 are dedicated to the riser cards for system memory. The communication ports 21 are for electrical connection with peripherals or input/output devices. The riser sockets 22, 23 are configured for the insertion of the riser cards 31, 32. On the riser cards 31, 32, several memory sockets 311, 321 are equipped for memory modules, such as DIMMs (Dual Inline Memory Modules) for expansibility of system memory.

In the embodiment of the present invention, the fastening assembly has two holders 41, 42, located opposite to each other and adjacent to the two lateral edges of the riser cards 31, 32. Each of the holders 41, 42 has one top bar 413/423 on the top, while the top bar 413(423) has two pillars 411, 412(421, 422) extended downwards to fix onto the mother board 20. Two thin, flat fixing pieces 415, 425 are utilized to couple with the pillars 411, 412(421, 422). Generally, the fixing piece and the corresponsive pillars are located at the opposite sides of the mother board. The fixing pieces 415,425 may be used to fasten the pillars 411, 412(421, 422) of the same holder 41 (42), or to fasten the pillar pairs 411-421 and the pillar pairs 412-422 as well. That means, the fixing piece 415(425) will be parallel to the top bars 413(423) when fastening the same holder 41(42). In the other hand, the fixing piece 415(425) will be perpendicular to the top bars 413(423) when fastening between the two holders 41 and 42. On the two ends of the top bar 413(423), two latches 51, 52 (53, 54) are configured for sliding and moving relatively to the top bar 413,423. The two latches 51, 52 (53, 54) may be practically combined as one for specific demands.

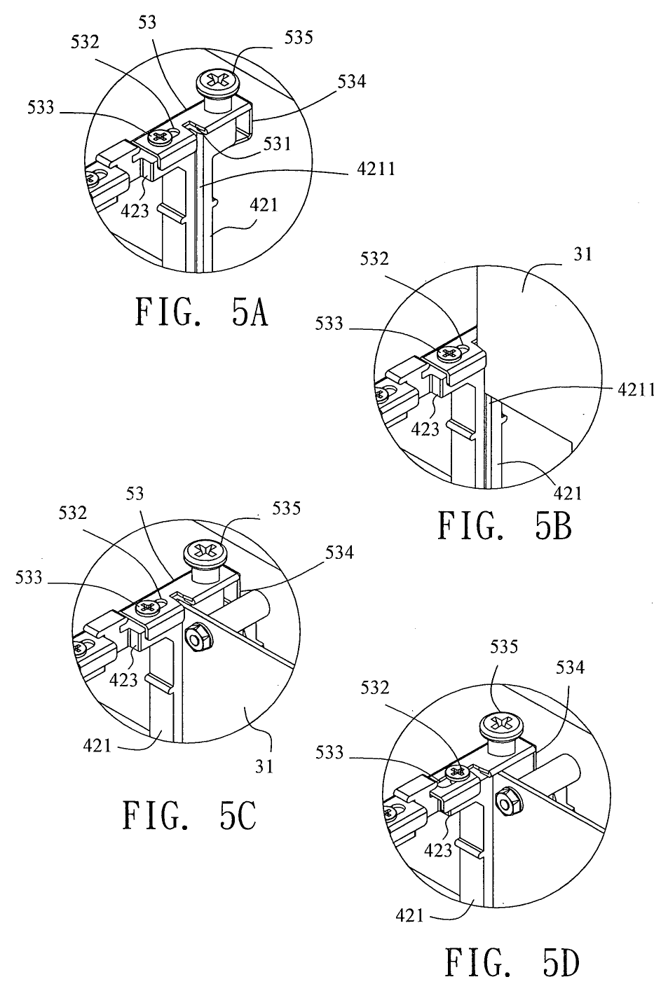

As shown in FIG. 5A, the pillar 421 of the holder 42 has a holding groove 4211. The latch 53 includes an opening 531 to allow the riser card 31 to pass through. At one end of the latch 53, the limiting slot 532 is utilized to limit the movement of the latch 53 by cooperating with a limiting member 533. The limiting member 533 may be a limiting screw, as shown in the drawings, or a positioning protrusion extended from the top bar 423. Other concave-protrusion structures varied by those skilled in the art will be helpful, too. The outer end of the latch 53 is bended as a hook 534 to hook on the terminal of the top bar 413. This design not only prevents the latch 53 from raising up at the terminal portion, but also provides the movement stability during the sliding operation, and helps to position the latch 53 by cooperating with the fixing screw 535.

Accordingly, the riser card 31 may pass the opening 531 of the latch 53 and slide in the holding groove 4211 of the pillar 421. Please refer to FIG. 5B, the other holder 41 at the other side has the same structure to form a width range between the two holding grooves, helping to hold and limit the sliding movement of riser card 31. Next, as shown in FIG. 5C, push the riser card 31 downwards along the holding groove 4211, until the bottom interface (not shown) of the riser card 31 is inserted in the riser socket 23 (FIG. 3). At the moment, the whole riser card 31 will be held in the holding groove 4211. Then the latch 53 may slide along the top bar 423, as shown in FIG. 5D, to make the opening 531 removed from the holding groove 4211, and latch the holding groove 4211 to prevent the riser card 31 from moving off. The fixing screw 535 will be used now to fasten the latch 53 at this position. Meanwhile, the hook 534 will hook completely on the terminal of the top bar 423 to provide the riser card 31 additional stability for protecting against impact, vibration or crash. At the central portion of the top bar 423, a T-shaped protrusion (shown but not marked in the drawings) allows one end of the latch 53 to insert therein and help to fasten the latch.

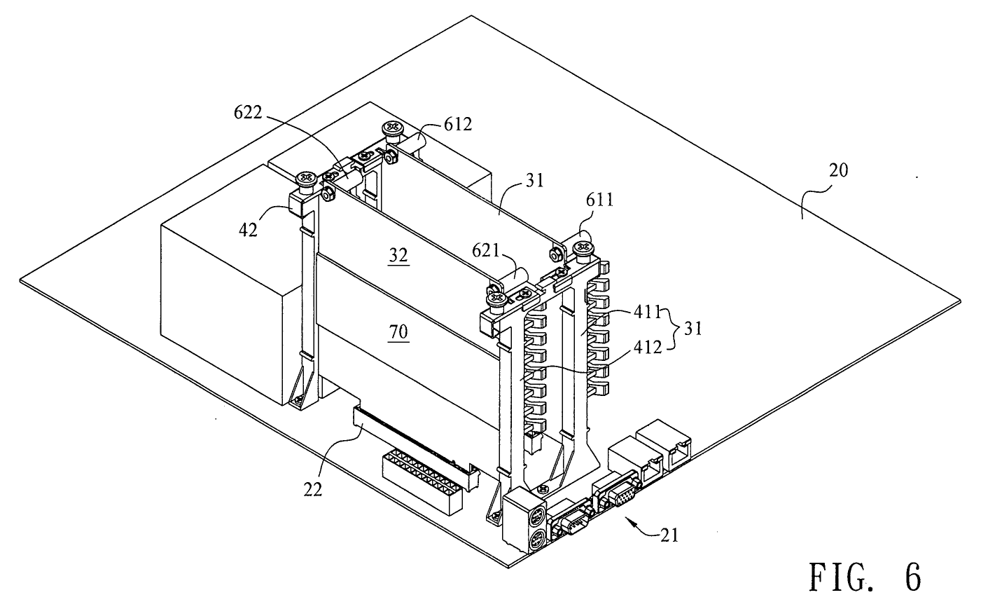

For practical applications, in a compact computer system with large amount of other components equipped on the mother board 20, the riser cards 31, 32 include several handles 611,612,621,622, as shown in FIG. 2 for simplifying the configuration operation of the riser cards 31, 32. The user may hold the handles 611,612,621,622 by hands, helping to insert the riser card 31, 32 into the riser sockets 22, 23 on the mother boards. Please refer to FIG. 6; a protection slice 70 is pasted on the rear surface of the riser card 32 to cover the pin terminals of the riser sockets 22(23) for operation safety, and meanwhile helping the precision of the sliding operation.

A simple variation of the above embodiments according to the present invention is to move the position of the latch from the bar of the holder to the riser card. The structure and composition of the latch may remain the same, including all elements such as the thin and flat body, the limiting slot with the limiting member, the fixing screw and the hook. The only difference is these elements are configured on the edges of the riser card. The latch may be capable of sliding or not. Possibly the latch may need a twist for the hook to hook the top bar of the holder. The fixing screw may be coupled to the top bar to fasten the riser card between the riser socket, and the holders. The handle may be fastened on the top of the riser card or on the latch.

Basically, the amount of the grooves includes in one holder depends on the amount of the riser cards. One pillar may have more than one groove, if necessary. For example, a wider pillar may have two or three grooves. So the amount and the shape of the pillar should not be limited. Furthermore, in specific cases with strong mechanical strength, one holder will be enough for fastening two or more said riser cards, with the assistance of the riser sockets.

Similarly, at the bottom of the pillar the holder may be configured with one (or more) bottom bar (shown but not marked in the drawings) to make the holder a solid framework. The triangle supports around the bottom of the pillar further provides more fastening strength. In addition, the holders disclosed in the embodiments are made of aluminum extrusion. But it is still practical for variations that meet the structural features of the holders.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A fastening assembly for a plurality of riser cards, each of the riser cards having a plurality of memory sockets for configuring with a plurality of memory modules, and the riser cards being inserted into corresponsive riser sockets of a mother board respectively, the fastening assembly comprising:
at least one holder configured adjacent to the riser cards, having a top bar and at least one pillar, the pillar being extended from the top bar to couple to the mother board and having at least one holding grooves holding the edges of the corresponsive riser cards and enabling the riser cards to slid therein and insert towards the riser sockets; and
at least one latch configured on the top bar of the holder for moving relatively to the top bar and blocking the holding grooves, thereby preventing the riser cards from moving off.

2. The fastening assembly of claim 1, further comprising at least one handle configured on the top of each of the riser cards.

3. The fastening assembly of claim 1, further comprising at least one fixing piece to fasten the pillar with the mother board, the fixing piece being parallel or perpendicular to the top bar.

4. The fastening assembly of claim 1, wherein the latch comprises a limiting slot to cooperate with a limiting member of the top bar for limiting the movement of the latch.

5. The fastening assembly of claim 4, wherein the limiting member is a positioning protrusion extended from the top bar.

6. The fastening assembly of claim 4, wherein the limiting member is a limiting screw.

7. The fastening assembly of claim 1, wherein the latch comprises a fixing screw for fastening the latch on the top bar.

8. The fastening assembly of claim 1, wherein the latch comprises a hook for hooking a terminal of the top bar.

9. The fastening assembly of claim 1, wherein the holder further comprises a bottom bar at the bottom of the pillar.

10. The fastening assembly of claim 1, wherein the top bar further comprising a T-shaped protrusion to allow one end of the latch to insert therein and help to fasten the latch.

11. The fastening assembly of claim 1, wherein the holder further comprises at least one triangle support around the bottom of the pillar.

12. A fastening assembly for a plurality of riser cards, each of the riser cards having a plurality of memory sockets for configuring with a plurality of memory modules, and the riser cards being inserted into corresponsive riser sockets of a mother board respectively, the fastening assembly comprising:
at least one holder configured adjacent to the riser cards, having a top bar and at least one pillar, the pillar being extended from the top bar to couple to the mother board and having at least one holding grooves holding the edges of the corresponsive riser cards and enabling the riser cards to slid therein and insert towards the riser sockets; and
at least one latch configured on the riser cards to couple with the top bar of the holder and prevent the riser cards from moving off.

13. The fastening assembly of claim 12 further comprising at least one handle configured on the top of each of the riser cards.

14. The fastening assembly of claim 12 further comprising at least one handle configured on the latch.

15. The fastening assembly of claim 12 further comprising at least one fixing piece to fasten the pillar with the mother board, the fixing piece being parallel or perpendicular to the top bar.

16. The fastening assembly of claim 12, wherein the latch comprises a limiting slot to cooperate with a limiting member of the top bar for limiting the movement of the latch.

17. The fastening assembly of claim 16, wherein the limiting member is a positioning protrusion extended from the top bar.

18. The fastening assembly of claim 16, wherein the limiting member is a limiting screw.

19. The fastening assembly of claim 12, wherein the latch comprises a fixing screw for fastening the latch on the top bar.

20. The fastening assembly of claim 12, wherein the latch comprises a hook for hooking the top bar.
